(19) United States
(12) Patent Application Publication
(10) Pub. No.: US 2015/0170969 A1
(43) Pub. Date: Jun. 18, 2015

(54) DEVICE WAFER PROCESSING METHOD

(71) Applicant: DISCO CORPORATION, Tokyo (JP)

(72) Inventor: Yasutaka Mizomoto, Tokyo (JP)

(21) Appl. No.: 14/561,941

(22) Filed: Dec. 5, 2014

(30) Foreign Application Priority Data
Dec. 17, 2013 (JP) 2013-259993

(51) Int. Cl. H01L 21/78; H01L 21/304; H01L 21/683

(52) U.S. Cl. CPC H01L 21/78; H01L 21/6835; H01L 21/304

(57) ABSTRACT

In a plate attaching step, a plate is attached to a front side of a device wafer through an adhesive. In a grinding step, the device wafer is held by a holding table through the plate, and an exposed back side of the device wafer is ground by grinding means to thin the device wafer down to a predetermined thickness. In a dicing step, the device wafer is divided along division lines from the side of the back side thereof, to form a plurality of chips. In a picking-up step, the chips are individually picked up from the plate. The plate is substantially the same as the device wafer in size, and, therefore, an increase in the size of a dicing apparatus can be restrained even when the device wafers to be processed are enlarged in diameter.

### BACKGROUND OF THE INVENTION

1. Field of the Invention

The present invention relates to a method for processing a device wafer having a plurality of devices formed on a front side thereof.

2. Description of the Related Art

At the time of dicing of a device wafer, a dicing tape attached to an annular frame having an opening with an inside diameter greater than an outside diameter of the device wafer, which has a plurality of devices formed on the front side thereof, is attached to a back side of the device wafer, whereby the device wafer is mounted to the frame through the dicing tape. Thereafter, the device wafer is divided into chips configured on a device basis. In this manner, the individual chips formed upon the division are prevented from being dispersed, and easy handling of the device wafer before the division and easy handling of the chips after the division are realized (see Japanese Patent Laid-Open No. 2003-243483, for example).

### SUMMARY OF THE INVENTION

In a conventional dicing apparatus, however, a frame greater than a device wafer is held and conveyed by conveying means, which causes an increase in apparatus size. Particularly where the device wafer has a large diameter (for example, a diameter of 450 mm), the frame is further enlarged, leading to a larger-sized dicing apparatus. On the other hand, there is a demand for a smaller-sized dicing apparatus.

Accordingly, it is an object of the present invention to provide a device wafer processing method which enables processing of device wafers while using a small-sized dicing apparatus.

In accordance with an aspect of the present invention, there is provided a method of processing a device wafer having devices formed respectively in regions sectioned by a plurality of intersecting division lines on a front side thereof, the method including: a plate attaching step of attaching a plate to the front side of the device wafer through an adhesive; a grinding step of holding the device wafer by a holding table through the plate so as to expose a back side of the device wafer, and grinding the exposed back side of the device wafer by grinding means to thin the device wafer down to a predetermined thickness; a dicing step of dicing, after the grinding step is conducted, the device wafer along the division lines from the back side of the device wafer so as to form a plurality of chips; and a picking-up step of picking up the chips individually from the plate after the dicing step is conducted.

Preferably, the adhesive is an adhesive having an adhesive force lowered when an external stimulus is applied thereto, and the chips are picked up after the external stimulus is applied to the adhesive, in the picking-up step. Preferably, in the picking-up step, a first one of the chips is picked up through application of the external stimulus to that region of the adhesive which corresponds to the first one of the chips, and thereafter a second one of the chips that is to be picked up next is picked up through application of the external stimulus to that region of the adhesive which corresponds to the second one of the chips.

According to the method of processing a device wafer in accordance with the described aspect of the invention, the device wafer is attached not to a dicing tape but to a plate, and dicing is conducted in that condition. While an annular frame in ordinary use is greater in size than the device wafer, the plate is substantially the same as the device wafer in size. Therefore, an increase in the size of a dicing apparatus can be restrained, even when the device wafers to be processed are enlarged in diameter. In addition, the plate serves as a protective member for protecting the devices during backside grinding. Therefore, it is unnecessary to especially attach a surface protective member to the device wafer when the device wafer is subjected to a grinding step. This makes it possible to enhance productivity and to reduce processing cost.

An adhesive having an adhesive force lowered when an external stimulus is applied thereto is used as the adhesive, and picking up of each of the chips is conducted after the external stimulus is applied in the picking-up step. This facilitates the picking-up operation.

In the picking-up step, a first chip is picked up through application of an external stimulus to that region of the adhesive which corresponds to the first chip, and thereafter a second chip to be picked up next is picked up through application of the external stimulus to that region of the adhesive which corresponds to the second chip. Thus, the external stimulus is applied only to the chip which is about to be picked up. This makes it possible to prevent the chips yet to be picked up from being peeled and dispersed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a device wafer;

FIG. 2 is a perspective view showing a manner in which an adhesive is applied to a plate;

FIG. 3 is a perspective view of a device wafer with the plate attached thereto;

FIG. 4 is a perspective view illustrating a grinding step;

FIG. 5 is a perspective view illustrating a dicing step;

FIG. 6 is a side sectional view illustrating the dicing step;

FIG. 7 is a side sectional view illustrating another dicing step;

FIG. 8 is a side sectional view showing a manner in which the adhesive force of an adhesive is lowered in a picking-up step; and

FIG. 9 is a side sectional view showing a manner in which a chip is picked up in the picking-up step.

### DETAILED DESCRIPTION OF THE PREFERRED EMBODIMENT

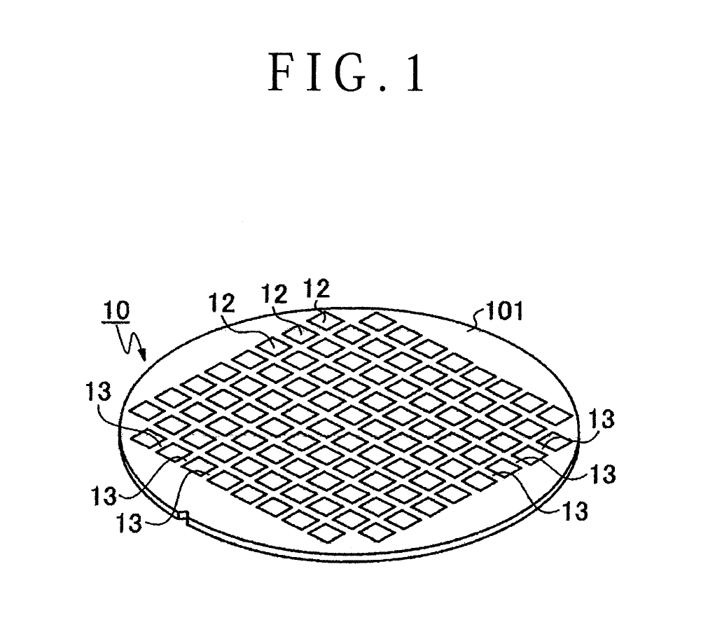

A device wafer 10 depicted in FIG. 1 is formed in a disk shape, and has a plurality of devices 12 formed on a front side 101 thereof. The devices 12 are formed in regions sectioned by a plurality of intersecting division lines 13 on the front side 101. The device wafer 10 is cut along the division lines 13, whereby the device wafer 10 is divided on the basis of each of the devices 12, to form a plurality of chips.

(1) Plate Attaching Step

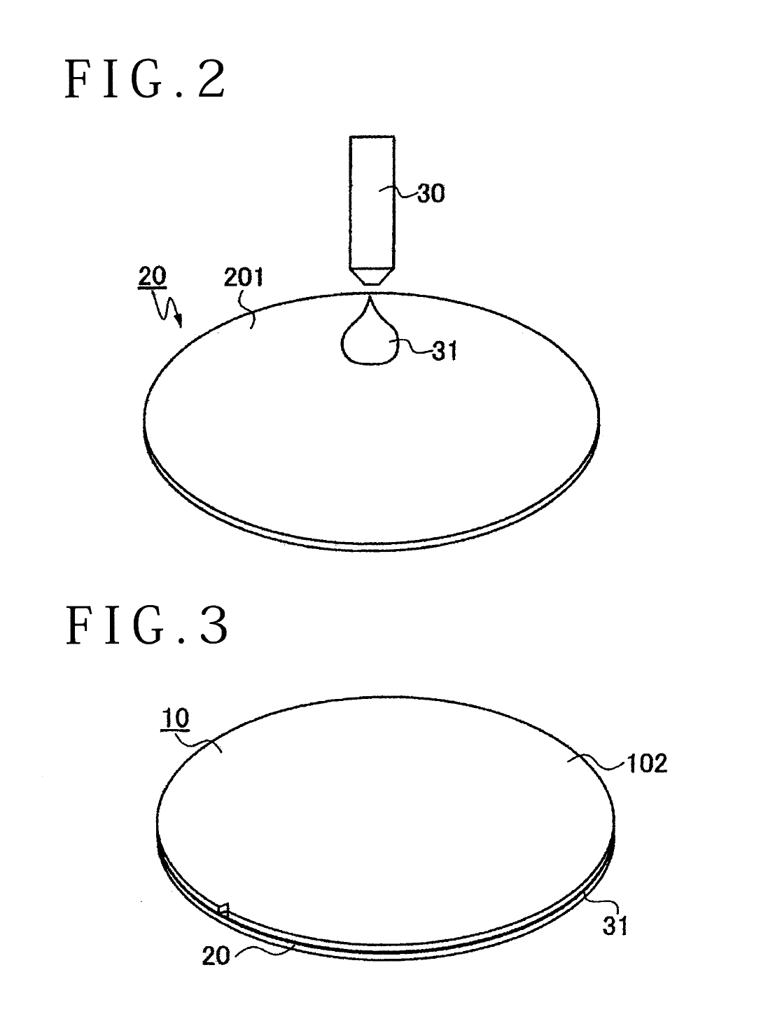

As depicted in FIG. 2, an adhesive 31 is supplied dropwise to a front side 201 of a disk-shaped plate 20 by adhesive applying means 30, and is made to coat the front side 201 by spin coating, for example. The plate 20 is formed from a material (e.g., glass) that does not deform easily and is transmissive to UV (ultraviolet) rays. As the adhesive 31, there is used one whose adhesive force is lowered upon irradiation with UV rays, thereby permitting easy peeling of the adhered matter. For instance, use is made of an adhesive 31 containing mixed therein microcapsules or a foaming agent for expansion or foaming upon irradiation with UV rays. The adhesive applying means 30 may be so configured as to supply dropwise a liquid or gelled adhesive 31 to the plate 20, or may be so configured as to attach a sheet-shaped piece of an adhesive 31 to the front side 201 of the plate 20.

Next, as illustrated in FIG. 3, the device wafer 10 is inverted upside down, and the front side 101 of the device wafer 10 is faced to and attached to the front side 201 of the plate 20, leaving a back side 102 of the device wafer 10 exposed. Consequently, the plate 20 is attached to the front side 201 of the device wafer 10 through the adhesive 31.

(2) Grinding Step

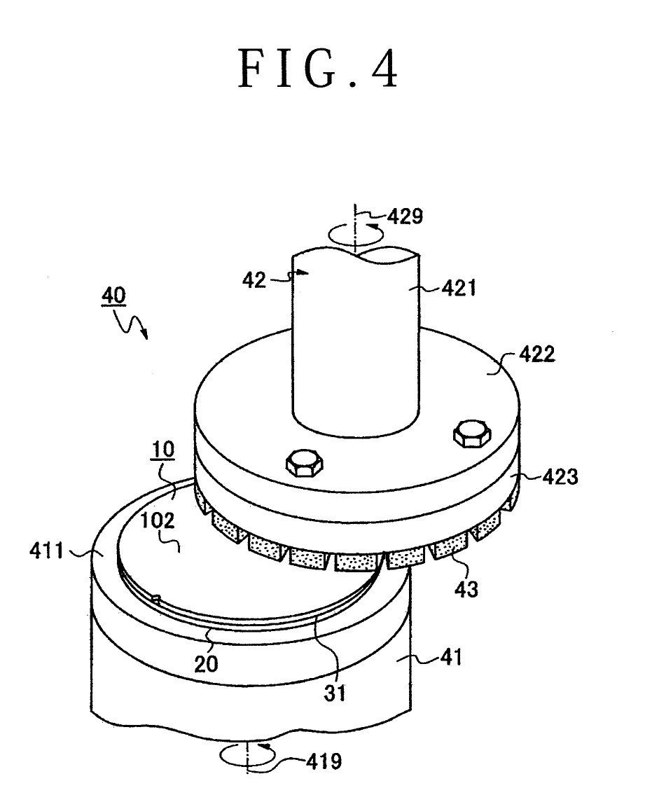

Subsequently, as shown in FIG. 4, using a grinding apparatus 40 which includes a holding table 41 for holding the device wafer 10 and grinding means 42 for grinding the device wafer 10 held by the holding table 41, the back side 102 of the device wafer 10 is ground to thin the device wafer 10 down to a predetermined thickness. The device wafer 10 is mounted on a holding surface 411 of the holding table 41, in such a manner that the side of the plate 20 is on the lower side and the back side 102 of the device wafer 10 is exposed, whereby the device wafer 10 is held by the holding table 41 through the plate 20.

On the other hand, the grinding means 42 includes a shaft portion 421, a mount 422 attached to a lower end of the shaft portion 421, and a grinding wheel 423 which is mounted to the mount 422 and which has a plurality of grindstones 43 fixed in an annular pattern. While rotating the holding table 41 about a rotation axis 419 and rotating the grindstones 43 mounted in the grinding means 42 about a rotation axis 429, the grindstones 43 are brought into contact with the back side 102 of the device wafer 10, thereby grinding the back side 102 of the device wafer 10. By this, the device wafer 10 is reduced in thickness. The grinding apparatus 40 finishes grinding when the device wafer 10 has just come to have a predetermined thickness.

(3) Dicing Step

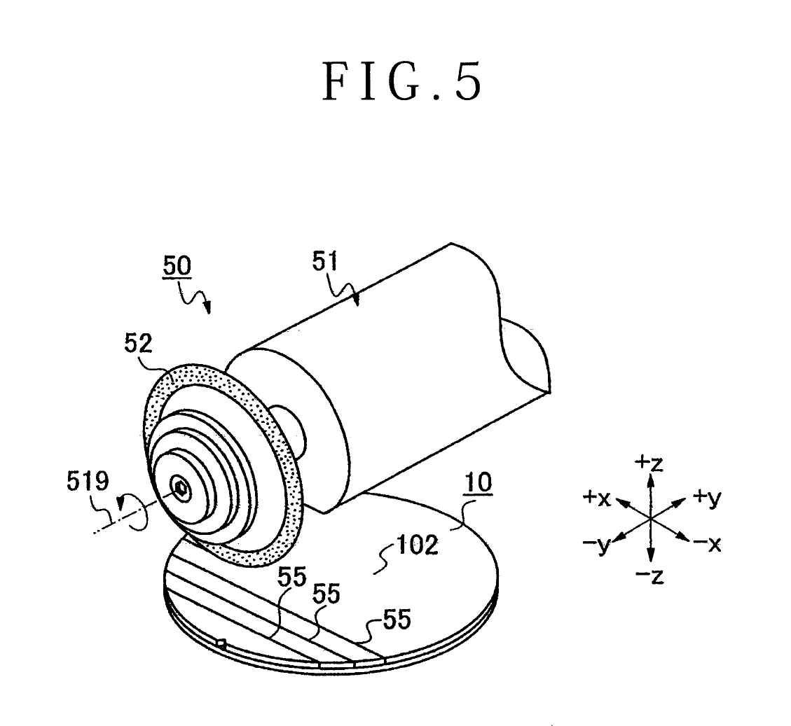

After the grinding step is performed, dicing of the device wafer 10 into individual chips is conducted using a cutting apparatus 50 depicted in FIG. 5. The cutting apparatus 50 includes cutting means 51 having a cutting blade 52 which can be rotated about a rotation axis 519 oriented in a Y-axis direction. One of the division lines 13 formed on the front side 101 of the device wafer 10 is detected by imaging it from the side of the back side 102 of the device wafer 10 by an infrared camera, for example, and positional matching between the detected division line 13 and the cutting blade 52 in the Y-axis direction is conducted. Thereafter, while moving the device wafer 10 in an X-axis direction and rotating the cutting blade 52, the cutting means 51 is lowered, to cut the device wafer 10 from the side of the back side 102 of the device wafer 10, thereby forming a groove 55.

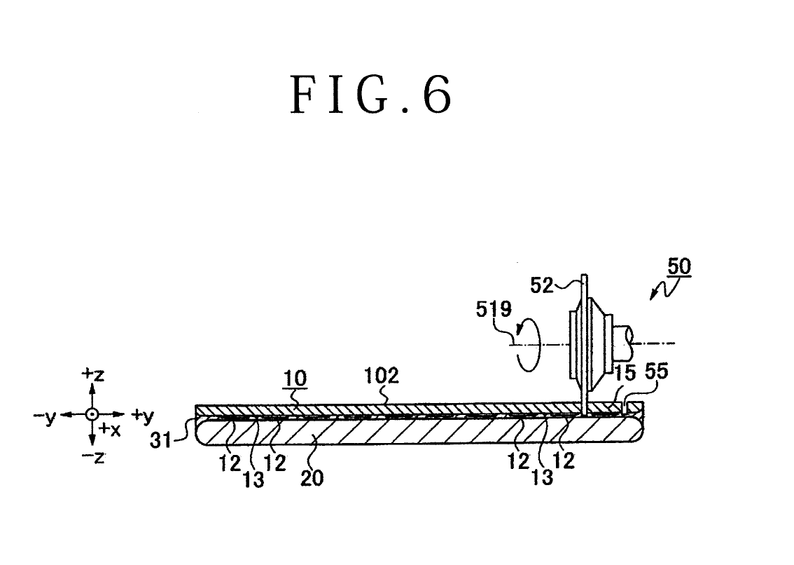

As illustrated in FIG. 6, the groove 55 is formed along the division line 13 of the device wafer 10, to such a depth as to completely cut the device wafer 10. When the cutting is conducted in the same manner in the crossing directions of the division lines for all the division lines, the device wafer 10 is divided (diced) into the plurality of chips 15. Each of the chips 15 has one device 12.

In the case where the plate 20 is formed of glass, a configuration may be adopted in which the device wafer 10 is imaged from the side of the front side 101 through the plate 20 to detect the pattern on the front side 101, thereby positioning the cutting blade 52 to the division line 13. While the annular frame in ordinary use in dicing is greater in size than the device wafer 10, the plate 20 is substantially the same as the device wafer 10 in size. Therefore, an increase in the size of a dicing apparatus can be restrained, even when the device wafer 10 to be processed are enlarged in diameter. In addition, the plate 20 serves as a protective member for protecting the devices 12 during the grinding step. Therefore, it is unnecessary to especially attach another surface protective member to the device wafer 10 in the instance of the grinding step. This makes it possible to enhance productivity and to reduce processing cost.

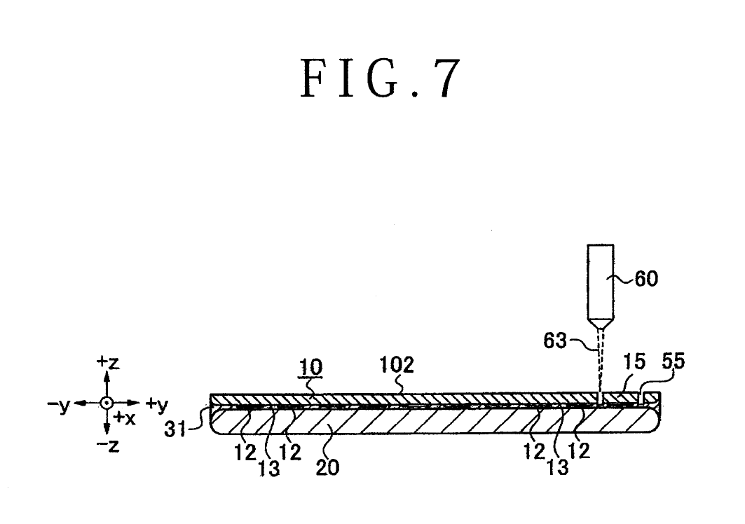

Instead of the cutting apparatus 50, a laser irradiation apparatus 60 as depicted in FIG. 7 may be used to divide the device wafer 10. For instance, the laser irradiation apparatus 60 applies a laser beam 63 to the device wafer 10 along the division lines 13 from the side of the back side 102 of the device wafer 10, to effect ablation, thereby fully cutting the device wafer 10. The application of the laser beam 63 may be conducted in a plurality of passes, as required.

(4) Picking-Up Step

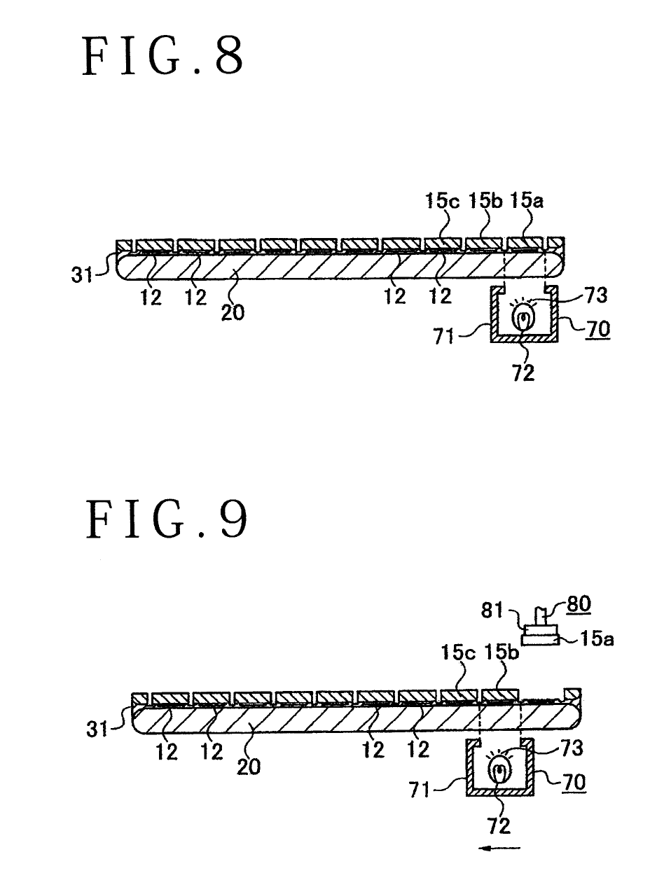

After the dicing step is carried out, use is made of an external stimulus applying apparatus 70 such as a UV irradiation apparatus wherein a light source 72 such as a light emitting diode for radiating UV rays is provided inside a mask 71, so as to apply an external stimulus to the adhesive 31 and thereby to lower the adhesive force of the adhesive 31, as illustrated in FIG. 8.

The external stimulus applying apparatus 70 irradiates that region of the adhesive 31 which corresponds to one of the chips (e.g., a first chip 15a) with UV rays. The mask 71 intercepts the UV rays radiated from the light source 72 so that the external stimulus is not applied to those regions of the adhesive 31 which correspond to the other chips (e.g., a second chip 15b, a third chip 15c, and so on). The external stimulus applying apparatus 70 may be configured to have a lens for condensing the UV rays radiated from the light source 72 into that region of the adhesive 31 which corresponds to the one of the chips.

After that region of the adhesive 31 which corresponds to the first chip 15a is irradiated with UV rays, a picking-up apparatus 80 having a collet 81 is used to pick up from the plate 20 the chip 15a such that the adhesive force of the adhesive 31 has been lowered in the region corresponding thereto, as shown in FIG. 9. Thereafter, the external stimulus applying apparatus 70 and the device wafer 10 are relatively moved, and the external stimulus applying apparatus 70 applies an external stimulus to that region of the adhesive 31 which corresponds to the second chip 15b to be picked up next. After the second chip 15b is picked up by the picking-up apparatus 80, the external stimulus applying apparatus 70 applies the external stimulus to that region of the adhesive 31 which corresponds to the third chip 15c to be picked up next.

In this way, the chips are sequentially picked up one by one. The external stimulus is applied only to that region of the adhesive 31 which corresponds to one chip, the chip such that the external stimulus has been applied to the region corresponding thereto is picked up, and this process is repeated. This not only facilitates the picking-up operation but also ensures the following. At the time of picking up a chip, the adhesive 31 adhering to the chip about to be picked up has been lowered in adhesive force, so that the chip can be picked up easily. In addition, since the adhesive 31 adhering to the other chips has not yet been lowered in adhesive force, a risk that those chips which have not yet come to be picked up might be peeled inadvertently and be dispersed can be avoided.

While the adhesive 31 is applied to the plate 20 and the device wafer 10 is attached to the adhesive-coated plate in the plate attaching step mentioned above, the adhesive may be in the form of a sheet. For instance, the adhesive may be in the form of an adhesive double coated tape. In this case, an adhesive layer on one side of the adhesive double coated tape is adhered to the plate 20, whereas an adhesive layer on the other side forms an adhesive surface whose adhesive force is lowered when an external stimulus is applied thereto, and the latter adhesive layer contributes to attaching to the device wafer 10. It suffices for the adhesive to have an adhesive force which is lowered when an external stimulus is applied thereto, regardless of the kind of the external stimulus. For instance, an adhesive whose adhesive force is lowered by heating may be used. In the case where the external stimulus is not irradiation with UV rays, the plate 20 need not be formed from a UV-transmissive material. In such a case, therefore, the plate 20 may be formed of silicon, for example.

A configuration may be adopted in which a die bonding film (DAF: die attach film) is attached to the back side 102 of the device wafer 10 after the grinding step, and the device wafer 10 is divided together with the DAF in the dicing step.

It suffices for the grooves 55 formed in the dicing step to be formed to such a depth that the device wafer 10 can be completely cut and divided into the plurality of chips 15. The grooves 55 may pierce into the plate 20, or may pierce only into the adhesive 31. Where the grooves 55 do not pierce into the plate 20, the plate 20 can be reused, which is preferable in view of a reduced cost. When the adhesive 31 is formed in a large coating thickness, it is possible to easily avoid cutting into the plate 20 while realizing complete cutting of the device wafer 10.

The method for dividing the device wafer 10 in the dicing step is not restricted to the method by cutting with the cutting blade 52 and the method by applying the laser beam 63, but other methods may also be used, for example, a method by plasma etching.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a device wafer having devices formed respectively in regions sectioned by a plurality of intersecting division lines on a front side thereof, the method comprising:
a plate attaching step of attaching a plate to the front side of the device wafer through an adhesive;
a grinding step of holding the device wafer by a holding table through the plate so as to expose a back side of the device wafer, and grinding the exposed back side of the device wafer by grinding means to thin the device wafer down to a predetermined thickness;
a dicing step of dicing, after the grinding step is conducted, the device wafer along the division lines from the back side of the device wafer so as to form a plurality of chips; and
a picking-up step of picking up the chips individually from the plate after the dicing step is conducted.

2. The method according to claim 1,
wherein the adhesive is an adhesive having an adhesive force lowered when an external stimulus is applied thereto, and
the chips are picked up after the external stimulus is applied to the adhesive, in the picking-up step.

3. The method according to claim 2,
wherein in the picking-up step, a first one of the chips is picked up through application of the external stimulus to that region of the adhesive which corresponds to the first one of the chips, and thereafter a second one of the chips that is to be picked up next is picked up through application of the external stimulus to that region of the adhesive which corresponds to the second one of the chips.
